(19) United States
(12) Patent Application Publication
(10) Pub. No.: US 2025/0336374 A1
(43) Pub. Date: Oct. 30, 2025

(54) DISPLAY DEVICE

(71) Applicant: E Ink Holdings Inc., HSINCHU (TW)

(72) Inventors: Hsin-Chung WU, HSINCHU (TW); Chih-Chun CHEN, HSINCHU (TW); Wen-Chung YANG, HSINCHU (TW); Hung-Yi WU, HSINCHU (TW); Chien-Yuan WU, HSINCHU (TW); Chia-Yang CHENG, HSINCHU (TW); Jia Hong XU, HSINCHU (TW)

(21) Appl. No.: 19/185,240

(22) Filed: Apr. 22, 2025

Related U.S. Application Data
(60) Provisional application No. 63/637,892, filed on Apr. 24, 2024.

(51) Int. Cl. G09G 3/34; H05K 1/02; H05K 1/03

(52) U.S. Cl. CPC G09G 3/344; H05K 1/0277; H05K 1/036; G09G 2300/0408; H05K 2201/0154; H05K 2201/0355; H05K 2201/10128

(57) ABSTRACT

A display device includes a driving substrate, a flexible printed circuit board, a microcontroller unit, a driving integration circuit, and a trace. The driving substrate includes a top surface and a bottom surface. The flexible printed circuit board is electrically connected with the driving substrate and is disposed on the top surface of the driving substrate. The microcontroller unit is disposed on the top surface of the driving substrate. The driver integration circuit is disposed on the top surface of the driving substrate. The trace connects the microcontroller unit and the driver integration circuit. The trace is straight and is located on the top surface of the driving substrate.

### CROSS-REFERENCE TO RELATED APPLICATION

This application claims priority to U.S. Provisional Application Ser. No. 63/637,892, filed Apr. 24, 2024, which is herein incorporated by reference in its entirety.

### BACKGROUND

### Field of Invention

The present invention relates to a display device.

### Description of Related Art

In the current microcontroller unit package technology field, Au wires and lead-frame are utilized to connect the printed circuit board and the driving integration circuit. Then, the driving integration circuit is bonded onto a conductive pad on the printed circuit board by using the solders, and a mold compound is utilized for molding lastly. The microcontroller unit is located on the printed circuit board, and the driving substrate and the printed circuit board are connected by the flexible printed circuit board.

With such design, the distribution of the traces is complicated, the length is increased, and the impedance is increased. Multiple structures interference with each other, and therefore the volume of the mounted display device is enlarged. Accordingly, it is still a goal of research and development in this field to provide a display device that can solve the problems above.

### SUMMARY

The invention provides a display device.

In one embodiment, the display device includes a driving substrate, a flexible printed circuit board, a microcontroller unit, a driving integration circuit, and a trace. The driving substrate includes a top surface and a bottom surface. The flexible printed circuit board is electrically connected with the driving substrate and is disposed on the top surface of the driving substrate. The microcontroller unit is disposed on the top surface of the driving substrate. The driver integration circuit is disposed on the top surface of the driving substrate. The trace connects the microcontroller unit and the driver integration circuit. The trace is straight and is located on the top surface of the driving substrate.

In one embodiment, the driving substrate includes a display region and a periphery region, and wherein the microcontroller unit is located in the periphery region.

In one embodiment, the driving substrate is located in the periphery region.

In one embodiment, the periphery region of the driving substrate includes a connecting region located at a side of the driving substrate adjacent to the flexible printed circuit board.

In one embodiment, the display device further includes a conical granule Au bump connecting with the driving integration circuit and the top surface of the driving substrate.

In one embodiment, the display device further includes a non-conductive film disposed between the driving integration circuit and the top surface of the driving substrate.

In one embodiment, the display device further includes a waterproof adhesive disposed on the top surface of the driving substrate and covering the driving integration circuit.

In one embodiment, the microcontroller unit further includes a Bluetooth module.

In one embodiment, the flexible printed circuit board is folded reversely to the bottom surface of the driving substrate.

In one embodiment, the flexible printed circuit board includes a polyimide film, two resin layers, and two copper foil layers, and the two resin layers are respectively located between the polyimide film and the two copper foil layers.

In one embodiment, the display device further includes a microcontroller unit control circuit disposed on the flexible printed circuit board and electrically connected with the microcontroller unit.

In one embodiment, the display device further includes an outer shell wrapping the driving substrate, the flexible printed circuit board, and the microcontroller unit.

The invention provides a display device.

In one embodiment, the display device further includes a driving substrate, a flexible printed circuit board, a microcontroller unit, and a driving integration circuit. The driving substrate includes a display region and a periphery region. The flexible printed circuit board is electrically connected with the driving substrate and is disposed in the periphery region of the driving substrate. The microcontroller unit is disposed in the periphery region of the driving substrate. The driving integration circuit is disposed in the periphery region of the driving substrate.

In one embodiment, the driving substrate includes a top surface and a bottom surface, and the display device further includes a trace connecting the microcontroller unit and the driver integration circuit, wherein the trace is located on the top surface of the driving substrate.

In one embodiment, the trace is straight.

In one embodiment, the microcontroller unit is located on the top surface of the driving substrate.

In one embodiment, the periphery region includes a connecting region located at a side of the driving substrate adjacent to the flexible printed circuit board, and the trace is located at the periphery region.

In one embodiment, the trace is located between the display region and the flexible printed circuit board.

In one embodiment, the microcontroller unit is located between the display region and the flexible printed circuit board.

In one embodiment, the driving integration circuit is located between the display region and the flexible printed circuit board.

In the aforementioned embodiments, the microcontroller unit of the display device of the present disclosure is located on the top surface of the driving substrate, and is concentrated in the connecting region with the driving integration circuit. Therefore, the traces connecting the microcontroller unit and the driving integration circuit can be designed as straight and there is no need to pass through the flexible printed circuit board or a connector that is used to connecting the extra printed circuit board. With such design, length of the traces is reduced and the impedance is reduced. The display device of the present disclosure has the advantages of simplifying structure complicity and reducing volume. Since the process of mounting the driving substrate with a printed circuit board in a conventional method is omitted, therefore the process steps and time can be reduced and cost is lowered.

### BRIEF DESCRIPTION OF THE DRAWINGS

The invention can be more fully understood by reading the following detailed description of the embodiment, with reference made to the accompanying drawings as follows:

FIG. 1 is a side view of a display device according to one embodiment of the present disclosure.

FIG. 2 is a top view of a display device according to another embodiment of the present disclosure.

FIG. 3 is a schematic diagram of a package of the microcontroller unit of a display device according to another embodiment of the present disclosure.

FIG. 4 is a schematic diagram of a flexible printed circuit board according to one embodiment of the present disclosure.

FIG. 5 is a schematic diagram of a packaged display device in FIG. 1.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

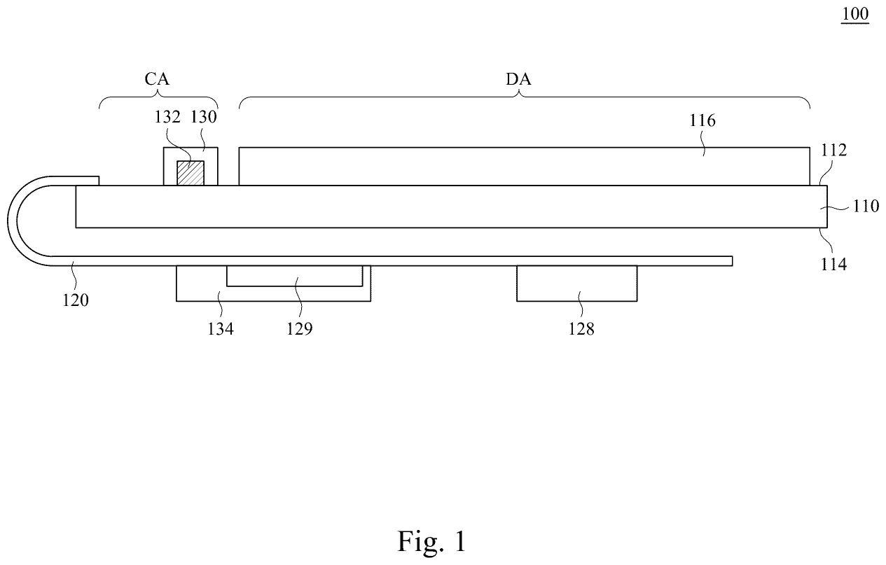

FIG. 1 is a side view of a display device 100 according to one embodiment of the present disclosure. The display device 100 includes a driving substrate 110, a flexible printed circuit board 120, and a microcontroller unit (MCU) 130. The driving substrate 110 includes a top surface 112 and a bottom surface 114. A display layer 116 is disposed on the top surface 112 of the driving substrate 110. The display device 100, for example, is an electrophoretic display, and the display layer 116 is an electronic ink layer. The flexible printed circuit board 120 is electrically connected to the driving substrate 110 and is disposed on the top surface 112 of the driving substrate 110. The microcontroller unit 130 is disposed on the top surface 112 of the driving substrate 110, and is a system on panel (SoP) design.

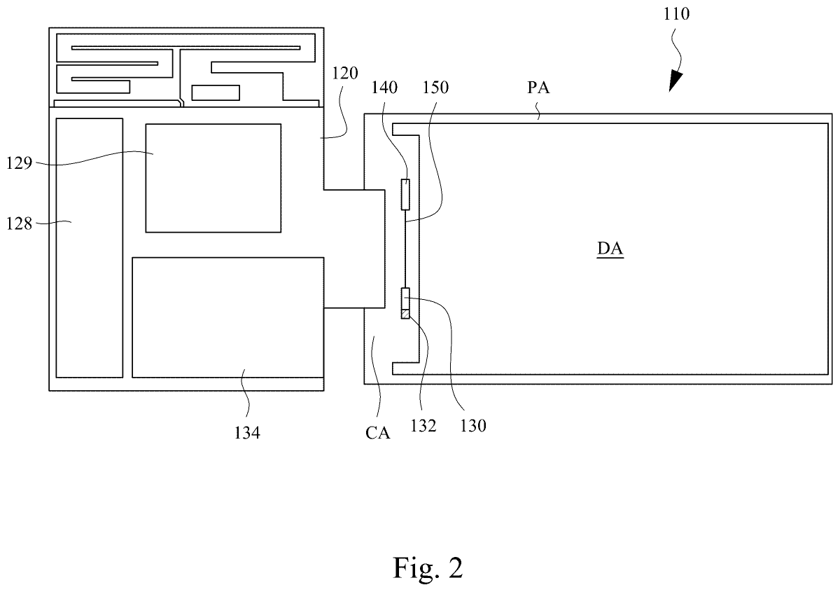

FIG. 2 is a top view of a display device 100 according to another embodiment of the present disclosure. In the FIG. 2, the flexible printed circuit board 120 is folded reversely to the bottom surface 114 of the driving substrate 110. The display device 100 further includes a driving integration circuit 140 and a trace 150 disposed on the top surface 112 of the driving substrate 110. The trace 150 is electrically connected with the microcontroller unit 130 and the driving integration circuit 140. The microcontroller unit 130 further comprises a Bluetooth module 132. The Bluetooth module 132 can be a low-power consumption and is embedded in the microcontroller unit 130.

The driving substrate 110 includes a display region DA and a periphery region PA. The microcontroller unit 130 and the driving integration circuit 140 are disposed on the connecting region CA of the periphery region PA adjacent to the flexible printed circuit board 120.

In a conventional display device, the flexible printed circuit board is connected with a printed circuit board. The microcontroller unit is disposed on the printed circuit board, and is a system on PCB (SoP) design. Therefore, the traces in the conventional design are required to pass through the flexible printed circuit board, a connector, and the printed circuit board. As a result, length of the traces is increased and multiple turning sections are required.

The microcontroller unit 130 of the display device 100 of the present disclosure is disposed on the driving substrate 110, and is concentrated in the connecting region CA. Therefore, the traces 150 are designed as straight and there is no need to pass through the flexible printed circuit board 120 or a connector that is used to connecting the extra printed circuit board. With such design, length of the traces is reduced and the impedance is reduced.

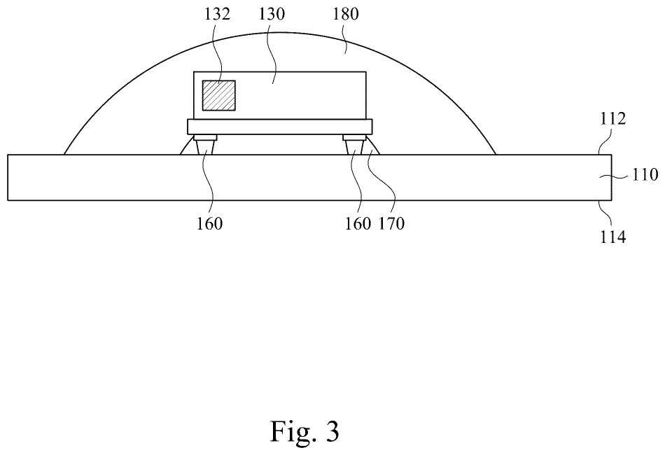

FIG. 3 is a schematic diagram of a package of the microcontroller unit 130 of a display device 100 according to another embodiment of the present disclosure. The display device 100 further includes a conical granule Au bump 160, a non-conductive film 170, and a waterproof adhesive 180. The conical granule Au bump 160 is connected with the driving integration circuit 140 and the top surface 112 of the driving substrate 110. The non-conductive film 170 is disposed between the driving integration circuit 140 and the top surface 112 of the driving substrate 110, such that the driving integration circuit 140 is adhered to the top surface 112. The waterproof adhesive 180 is disposed on the top surface 112 of the driving substrate 110 and covers the driving integration circuit 140. For example, the waterproof adhesive 180 is a room temperature vulcanized (RTV) silicon rubber.

Wires and lead-frame are utilized in the conventional driving integration circuit package method to connect the printed circuit board and the driving integration circuit. Then, the driving integration circuit is bonded onto a conductive pad on the printed circuit board by using the solders, and a mold compound is utilized for molding. The structures of the driving substrate and the system circuits on the printed circuit board each occupy an amount of the space thereon. When the driving substrate and the printed circuit board are connected by the flexible printed circuit board, it is necessary to consider the tolerance space for structural interference. As a result, the overall volume is increased.

Therefore, comparing to the conventional packager technology, the display device 100 of the present disclosure has the advantages of simplifying structure complicity and reducing volume. Since the process of mounting the driving substrate 110 with a printed circuit board in a conventional method is omitted, therefore the process steps and time can be reduced and cost is lowered.

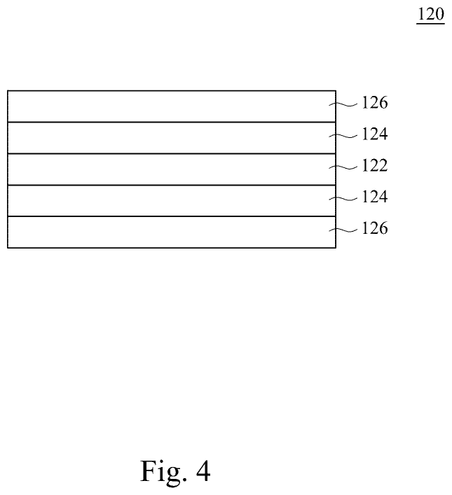

FIG. 4 is a schematic diagram of a flexible printed circuit board 120 according to one embodiment of the present disclosure. Reference is made to FIG. 1 and FIG. 4. The flexible printed circuit board 120 is folded reversely to the bottom surface 114 of the driving substrate 110. The flexible printed circuit board 120 includes a polyimide film 122, two resin layers 124, and two copper foil layers 126. The two resin layers 124 are respectively located between the polyimide film 122 and the two copper foil layers 126. In other words, the flexible printed circuit board of the present disclosure is a double layer design.

Reference is made to FIG. 2. The flexible printed circuit board 120 further includes battery circuit 128 and direct current 129. The direct current 129 is electrically connected to the driving integration circuit 140. The display device 100 further includes a microcontroller unit control circuit 134 disposed on the flexible printed circuit board 120 and electrically connected with the microcontroller unit 130.

With such double layer design of the flexible printed circuit board 120, the printed circuit board in a conventional method can be omitted. It is only required to integrate the passive elements (battery circuit 128, direct current 129, and the microcontroller unit control circuit 134) originally presented on the printed circuit board onto the flexible printed circuit board 120 and integrate the low-power consumption Bluetooth module 132 onto the microcontroller unit 130. With aforementioned structural design, the overall length of the traces 150 of the display device is reduced and the impedance is reduced.

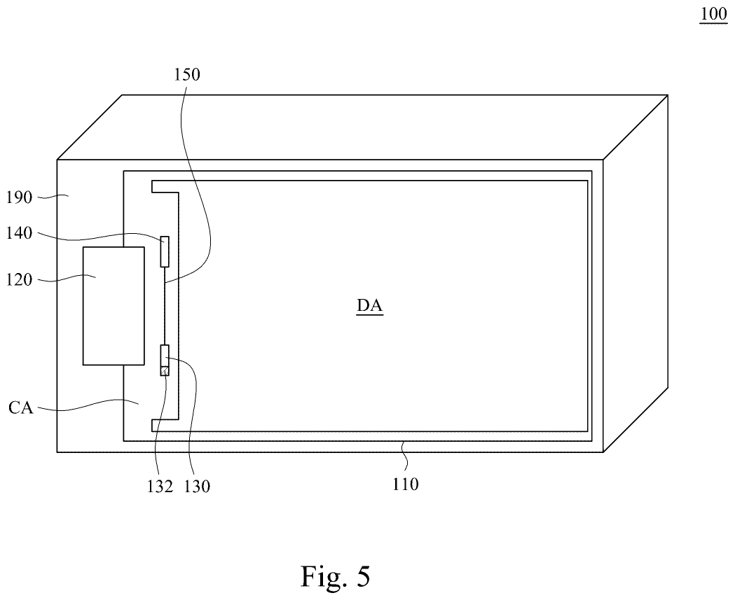

FIG. 5 is a schematic diagram of a packaged display device 100 in FIG. 1. The display device 100 further includes an outer shell 190 wrapping the driving substrate 110, the flexible printed circuit board 120, and microcontroller unit 130. The microcontroller unit 130 of a mounted display device 100 is located at the top part of the entire display device. With the protection of the outer shell 190, the safety, the temperature resistance, and the humidity resistance of the microcontroller unit 130 on the top surface 112 is maintained.

In summary, the microcontroller unit of the display device of the present disclosure is located on the top surface of the driving substrate, and is concentrated in the connecting region with the driving integration circuit. Therefore, the traces connecting the microcontroller unit and the driving integration circuit can be designed as straight and there is no need to pass through the flexible printed circuit board or a connector that is used to connecting the extra printed circuit board. With such design, length of the traces is reduced and the impedance is reduced. The display device of the present disclosure has the advantages of simplifying structure complicity and reducing volume. Since the process of mounting the driving substrate with a printed circuit board in a conventional method is omitted, therefore the process steps and time can be reduced and cost is lowered. With such double layer design of the flexible printed circuit board, the printed circuit board in a conventional method can be omitted. It is only required to integrate the passive elements originally presented on the printed circuit board onto the flexible printed circuit board and integrate the low-power consumption Bluetooth module onto the microcontroller unit. With aforementioned structural design, the overall length of the traces 150 of the display device is reduced and the impedance is reduced.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A display device, comprising:
a driving substrate comprising a top surface and a bottom surface;
a flexible printed circuit board electrically connected with the driving substrate and disposed on the top surface of the driving substrate;
a microcontroller unit disposed on the top surface of the driving substrate;
a driving integration circuit disposed on the top surface of the driving substrate; and
a trace connecting the microcontroller unit and the driving integration circuit, wherein the trace is located on the top surface of the driving substrate.

2. The display device of claim 1, wherein the driving substrate comprises a display region and a periphery region, and wherein the microcontroller unit is located in the periphery region.

3. The display device of claim 2, wherein the driving substrate is located in the periphery region.

4. The display device of claim 2, wherein the periphery region of the driving substrate comprises a connecting region located at a side of the driving substrate adjacent to the flexible printed circuit board.

5. The display device of claim 1, further comprising:
a conical granule Au bump connecting with the driving integration circuit and the top surface of the driving substrate.

6. The display device of claim 1, further comprising:
a non-conductive film disposed between the driving integration circuit and the top surface of the driving substrate.

7. The display device of claim 1, further comprising:
a waterproof adhesive disposed on the top surface of the driving substrate and covering the driving integration circuit.

8. The display device of claim 1, wherein the microcontroller unit further comprises a Bluetooth module.

9. The display device of claim 1, wherein the flexible printed circuit board is folded reversely to the bottom surface of the driving substrate.

10. The display device of claim 1, wherein the flexible printed circuit board comprises a polyimide film, two resin layers, and two copper foil layers, and the two resin layers are respectively located between the polyimide film and the two copper foil layers.

11. The display device of claim 1, further comprising:
a microcontroller unit control circuit disposed on the flexible printed circuit board and electrically connected with the microcontroller unit.

12. The display device of claim 1, further comprising:
an outer shell wrapping the driving substrate, the flexible printed circuit board, and the microcontroller unit.

13. A display device, comprising:
a driving substrate comprising a display region and a periphery region;
a flexible printed circuit board electrically connected with the driving substrate and disposed in the periphery region of the driving substrate;
a microcontroller unit disposed in the periphery region of the driving substrate; and
a driving integration circuit disposed in the periphery region of the driving substrate.

14. The display device of claim 13, wherein the driving substrate comprises a top surface and a bottom surface, and the display device further comprise:
a trace connecting the microcontroller unit and the driving integration circuit, wherein the trace is located on the top surface of the driving substrate.

15. The display device of claim 14, wherein the trace is straight.

16. The display device of claim 14, wherein the microcontroller unit is located on the top surface of the driving substrate.

17. The display device of claim 14, wherein the periphery region comprises a connecting region located at a side of the driving substrate adjacent to the flexible printed circuit board, and the trace is located at the periphery region.

18. The display device of claim 14, wherein the trace is located between the display region and the flexible printed circuit board.

19. The display device of claim 13, wherein the microcontroller unit is located between the display region and the flexible printed circuit board.

20. The display device of claim 13, wherein the driving integration circuit is located between the display region and the flexible printed circuit board.
